(19) United States
(12) Patent Application Publication
(10) Pub. No.: US 2025/0279389 A1
(43) Pub. Date: Sep. 4, 2025

(54) BONDING TOOL FOR BONDING DIES ONTO SUBSTRATES AND METHODS OF USE

(71) Applicant: TAIWAN SEMICONDUCTOR MANUFACTURING COMPANY, LTD., Hsinchu (TW)

(72) Inventors: Li-An WEN, Hsinchu (TW); Chien-An LAI, Hsinchu (TW); Yi Chen HO, Taichung (TW)

(21) Appl. No.: 18/591,700

(22) Filed: Feb. 29, 2024

(51) Int. Cl. H01L 23/00

(52) U.S. Cl. CPC H01L 24/80; H01L 24/74; H01L 2224/74; H01L 2224/80203; H01L 2224/80895; H01L 2224/80896

(57) ABSTRACT

Embodiments of the present disclosure provide a bonding tool for bonding dies onto substrates and a method that includes positioning a substrate and a plurality of dies over a substrate support of a bonding tool, wherein the plurality of dies are disposed on the substrate, and the substrate is surrounded by an edge ring, inflating a membrane of the bonding tool disposed above the substrate and the edge ring to expand the membrane downwards, wherein a polyetheretherketone (PEEK) layer attached to the membrane rests on the edge ring, and applying a force from the inflating membrane on the plurality of dies via the PEEK layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E illustrate views of various stages of bonding dies onto a substrate, in accordance with some embodiments.

FIG. 2 is a flowchart that illustrates a method of bonding dies onto a substrate, in accordance with some embodiments.

FIG. 3 is a perspective view of a membrane assembly that includes a membrane with a polymer layer attached, in accordance with some embodiments.

FIG. 4 is a partial sectional view that illustrates an inflation state of bonding a die onto the substrate, in accordance with some embodiments.

FIG. 5 is a schematic partial sectional view that illustrates a force application state of bonding a die onto the substrate, in accordance with some embodiments.

FIGS. 6A-6E illustrate views of various stages of bonding dies onto a substrate, in accordance with some embodiments.

FIG. 7 is a flowchart that illustrates an alternative method of bonding dies onto a substrate, in accordance with some embodiments.

FIG. 8 is a schematic sectional view that illustrates a first bonding step of forming a semiconductor device package, in accordance with some embodiments.

FIG. 9 is a schematic sectional view that illustrates a second bonding step of forming the semiconductor device package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of this disclosure provide a bonding tool for bonding dies onto substrates and associated methods. According to the methods described herein, particularly the use of a polymer layer between a bonding tool membrane and a die that is to be bonded, substantial increases in die yield, determined through wafer assurance test (WAT), can be achieved. For example, testing has shown increases in die yield of 10%-20% and die yields of 95%-100%. In addition, the methods described herein can reduce die shift and enhance final bonding strength on the order of about 0.5 J/m².

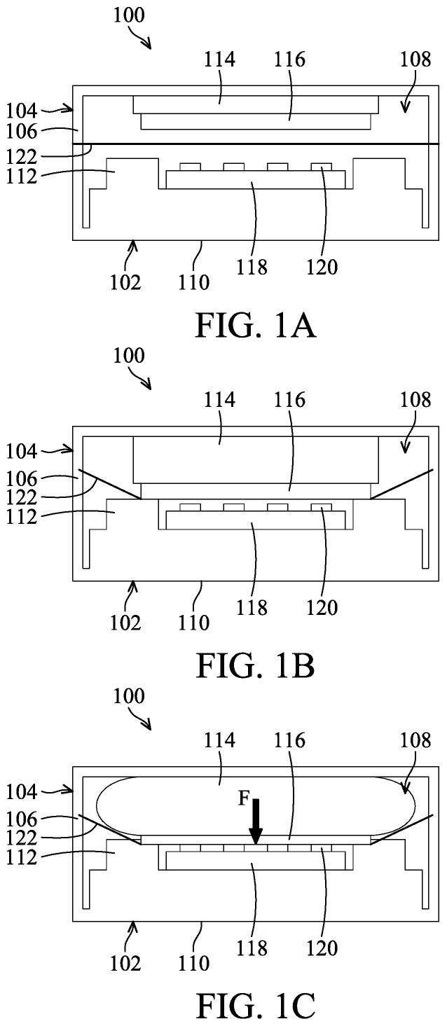

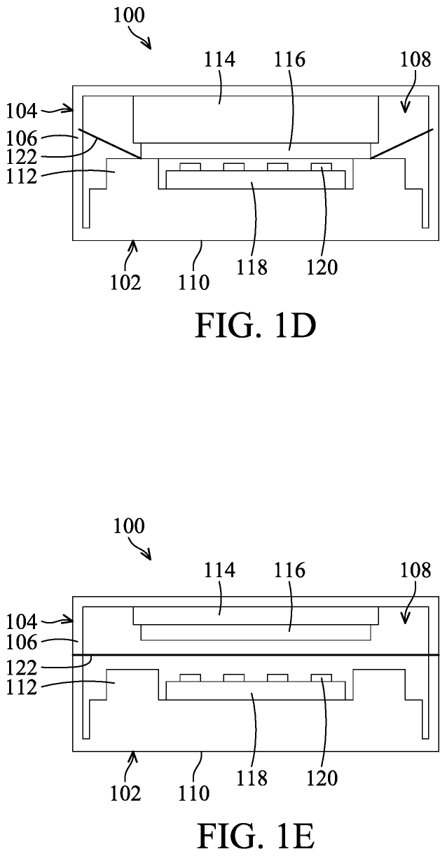

FIGS. 1A-1E illustrate views of various stages of bonding dies onto a substrate, in accordance with some embodiments. FIG. 2 is a flowchart that illustrates a method 200 of bonding dies onto a substrate, in accordance with some embodiments. Referring to FIG. 1A and FIG. 2 (block 210), a substrate and a plurality of dies that are to be bonded to the substrate are transferred, via a robot handler, from a factory interface to a substrate support of a bonding tool. As shown in FIG. 1A, a bonding tool 100 (e.g., a die press) includes a lower tray 102, an upper tray 104, and a seal ring 106 between the lower tray 102 and the upper tray 104. The lower tray 102 and/or the upper tray 104 are able to be moved away from each other and towards each other to open and close the bonding tool 100, respectively. For example, the lower tray 102 may be moved downwards in a substantially vertical direction and/or the upper tray 104 may be moved upwards in a substantially opposite vertical direction. The seal ring 106 is configured to form an airtight seal and/or a fluid tight seal between the lower tray 102 and the upper tray 104 when the lower tray 102 and the upper tray 104 are moved to a closed position of the bonding tool 100. The closed position is shown in FIGS. 1A-1E. The seal ring 106 may be an annular, elastomeric seal (e.g., an o-ring seal). A processing region 108 is defined between and/or within the lower tray 102 and the upper tray 104 and sealed by the seal ring 106. The processing region 108 may be in fluid communication with processing equipment attached to the bonding tool 100 (e.g., a pump, vacuum pump, inert gas source, valves, sensors, and/or other equipment).

The lower tray 102 includes a substrate support 110 attached to the lower tray 102 and an edge ring 112 on the substrate support 110. In some embodiments, the substrate support 110 and the edge ring 112 may be separate pieces that are attached together. For example, the edge ring 112 may be attached to an upper surface of the substrate support 110 that is facing away from the lower tray 102. In some other embodiments, the substrate support 110 and the edge ring 112 may be a single, unitary piece. The upper tray 104 includes a membrane 114 (which also may be referred to herein as a “cushion”) attached to the upper tray 104 and a polymer layer 116 attached to the membrane 114. The membrane 114 is disposed above the substrate support 110 and the edge ring 112. For example, the membrane 114 may be attached to a lower surface of the upper tray 104 that is facing towards the lower tray 102. Likewise, the polymer layer 116 may be attached to a lower surface of the membrane 114. The process described in connection with FIGS. 1A-1E and FIG. 2 may be referred to as an “auto handling” process because the polymer layer 116 is fixedly attached to the membrane 114 and is not handled by an operator during the process. The membrane 114 may be formed of a material that has relatively high elasticity compared to the polymer layer 116. For example, the membrane 114 may include primarily silicone. The polymer layer 116 may be formed of a material that is different from the material of the membrane 114. For example, the polymer layer 116 may have an elasticity substantially smaller than the elasticity of the membrane 114 (e.g., a ratio of elasticity between the membrane 114 and the polymer layer 116 may be greater than 10×, such as within a range between about 10× and about 100×). The polymer layer 116 may include primarily polyetheretherketone (PEEK). Based on the difference in elasticity between the membrane 114 and the polymer layer 116, the membrane 114 is configured to expand, in volume, to a far greater extent than the polymer layer 116. To account for this differential, the polymer layer 116 may be attached to the membrane 114 with a bonding technique that is able to withstand the relative difference in expansion between the two materials.

A substrate 118 and a plurality of dies 120 are positioned over the substrate support 110. The plurality of dies 120 are disposed on the substrate 118. For example, the plurality of dies 120 may be positioned on a top surface of the substrate 118 that is facing away from the substrate support 110. The substrate 118 is surrounded by the edge ring 112. The membrane 114 is disposed above the substrate 118 and the edge ring 112. As shown in FIG. 1A, the edge ring 112 extends above the plurality of dies 120. For example, as described in more detail below, the edge ring 112 has a height substantially greater than a combined height of the substrate 118 and a die of the plurality of dies 120.

The substrate 118 may include a semiconductor substrate, such as a wafer, chip, system on chip (SoC), or integrated system on chip (SoIC), among other examples. The plurality of dies 120 may include a semiconductor die that is to be attached to the semiconductor substrate, such as a wafer, chip, SoC, or SoIC, among other examples. The plurality of dies 120 may be arranged with respect to the substrate 118 according to a device layout that is to be formed using the die bonding process. For example, the plurality of dies 120 may be spaced apart across a diameter of the substrate 118.

The lower tray 102 and the upper tray 104 may include respective heating elements that enable respective temperatures of the lower tray 102 and the upper tray 104 to be controlled independently. In some embodiments, die bonding using the bonding tool 100 described herein includes a low temperature anneal. For example, the respective temperatures of the lower tray 102 and the upper tray 104 may be within a range between about 130° C. and about 150° C., such as about 140° C. In some embodiments, the respective temperatures of the lower tray 102 and the upper tray 104 may be set as the processing temperature for bonding the plurality of dies 120 to the substrate 118. In some embodiments, the glass transition temperature (Tc) of the material of the polymer layer 116 is within a range between about −40° C. and about +30° C. with respect to Tc, such as within a range between about −30° C. and about +20° C. with respect to Tc, such as within a range between about −20° C. and about +10° C. with respect to Tc, such as within a range between about −10° C. and about +10° C. with respect to Tc. Thus, in some embodiments, the material of the polymer layer 116 is determined by the processing temperature of the die bonding process. If the Tc of the material of the polymer layer 116 is substantially greater than the processing temperature, such as about 50° C. greater than the processing temperature, the polymer layer 116 may break under a force F exerted by the membrane 114. On the other hand, if the Tc of the material of the polymer layer 116 is substantially less than the processing temperature, such as about 50° C. less than the processing temperature, the polymer layer 116 may become too soft to transfer the force F uniformly to the plurality of dies 120.

As shown in FIG. 1A, a release film 122 is positioned (e.g., suspended) between the polymer layer 116 and the plurality of dies 120. The release film 122 may be formed of a material that does not adhere to the polymer layer 116, the substrate 118, or the plurality of dies 120. For example, without the release film 122, the polymer layer 116 may be susceptible to adhering to and causing damage to the substrate 118 and/or the plurality of dies 120 during the die bonding process. The release film 122 may be a plastic material that is different from the polymer layer 116. For example, the release film 122 may include primarily polytetrafluoroethylene (PTFE). In some embodiments, the release film 122 is a low-friction material (e.g., characterized with a smooth and/or slippery texture). In some embodiments, Tc of the release film 122 may be within a range between about 2× and about 5× compared to Tc of the polymer layer 116. The release film 122 may be one time use only and is configured to be replaced after each bonding step. For example, a roll of the release film 122 may be located at one end of the processing region 108, and the release film 122 is pulled across the processing region 108 to an opposite end of the processing region 108. The release film 122 may be pulled by any device, such as a roller. In some embodiments, after each die bonding process, the used release film 122 is pulled away from the processing region 108, and a new release film 122 from the roll is positioned above the substrate support 110.

Referring to FIG. 1B and FIG. 2 (block 220), the membrane 114 is inflated to expand the membrane 114, and the polymer layer 116 attached to the membrane 114, downwards towards the substrate 118. As the membrane 114 is inflated, a vertical distance between a bottom surface of the polymer layer 116 and a top surface of the edge ring 112 decreases. During inflation of the membrane 114, the polymer layer 116 contacts the release film 122. After contacting the polymer layer 116, the release film 122 moves downwards, with the polymer layer 116, towards the substrate 118. When the membrane 114 is inflated to a threshold volume (or threshold pressure), the polymer layer 116 contacts the edge ring 112 (e.g., via the release film 122), as shown in FIG. 1B. At this stage, the polymer layer 116 rests on the edge ring 112, and the release film 122 is disposed between the polymer layer 116 and the edge ring 112. For example, a diameter of the polymer layer 116 may be greater than an inner diameter of the edge ring 112 such that an outer portion of the polymer layer 116 overlaps with and rests on an inner portion of the edge ring 112. In some embodiments, the membrane 114 may be inflated by providing pressurized gas (e.g., inert gas or air) inside the membrane 114. For example, inflation of the membrane 114 may be based on a pressure differential between the membrane 114 and the processing region 108. The upper tray 104 of the bonding tool 100 may include one or more gas connections that are in fluid communication between the inside of the membrane 114 and inflation equipment attached to the bonding tool 100 (e.g., a pump, vacuum pump, pressurized gas source, valves, sensors, and/or other equipment).

When the polymer layer 116 first contacts the edge ring 112 via the release film 122, as shown in FIG. 1B, there is a gap between a top surface of a die, of the plurality of dies 120, and the bottom surface of the release film 122. In some embodiments, the gap may range from about 80 μm to about 120 μm. The membrane 114 may continue to be inflated after reaching the edge ring 112 causing an inner radial portion of the polymer layer 116 to advance across (or close) the gap to rest on the plurality of dies 120 and cause a force to be applied on the plurality of dies 120 as described in more detail below.

In some embodiments, inflating the membrane 114 at block 220 may include a first vacuum process that reduces pressure in the processing region 108 from atmospheric pressure (760 Torr) to about 5000 mTorr and a second vacuum process that further reduces pressure to less than about 1000 mTorr, such as less than about 100 mTorr, such as within a range between about 10 mTorr and about 100 mTorr. As the pressure in the processing region 108 is being reduced, the membrane 114 may be inflated simultaneously. In some embodiments, the vacuum and inflation process described above may occur over a total time period within a range between about 2 minutes and about 6 minutes, such as between about 3 minutes and about 5 minutes, such as about 4 minutes. In some embodiments, the first vacuum process may occur over a first time period T1 within a range between about 30 seconds and about 90 seconds, such as about 60 seconds. In some embodiments, the second vacuum process and inflation process, which can take place simultaneously, may occur over a second time period T2 within a range between about 2 minutes and about 4 minutes, such as about 3 minutes.

Referring to FIG. 1C and FIG. 2 (block 230), a force F is applied from the inflating membrane 114 on the plurality of dies 120 via the polymer layer 116. For example, when the polymer layer 116 first contacts the plurality of dies 120 via the release film 122 an initial force may be applied thereto. Thereafter, as the pressure in the membrane 114 is further increased, the force may increase, according to force=pressure×area, until the pressure reaches and maintains a target pressure that applies the force F. In some embodiments, the time that passes during application of the initial force and build-up of force up to, but not including, the force F, can be considered part of the second time period T2 described above. In some embodiments, after the force F is reached, the target pressure may be maintained, and the force F may be applied, for a third time period T3 within a range between about 20 minutes and about 30 minutes, such as about 25 minutes.

As described above, the polymer layer 116 may be formed of a material that is substantially inelastic. The force F from the membrane 114 pushes the polymer layer 116 towards the plurality of dies 120. Even though the material of the polymer layer 116 is substantially inelastic, the material of the polymer layer 116 is softened at the processing temperature, which is within 50° C. of the Tc of the material of the polymer layer 116. For example, at the processing temperature, a limited amount of ductility is imparted to the polymer layer 116 such that the polymer layer 116 can take the shape of the gap inside the edge ring 112. Thus, the portion of the polymer layer 116 located over the plurality of dies 120 may extrude across the gap uniformly. In other words, the inelastic property of the polymer layer 116, even though softened by the processing temperature, is beneficial to cause the force F to be uniformly applied on the plurality of dies 120. For example, the bottom surface of the inner radial portion of the polymer layer 116 may be substantially flat when the force F is being applied on the plurality of dies 120. In some embodiments, the force F may be set based on a processing temperature of the bonding tool 100. For example, the force F may be positively correlated with processing temperature. Higher processing temperatures (e.g., T>Tc) may cause the polymer layer 116 to be more ductile (less brittle) such that higher forces can be applied without causing the polymer layer 116 to crack. Likewise, lower processing temperatures (e.g., T<Tc) may cause the polymer layer 116 to be more brittle (less ductile) such that only relatively lower forces can be applied on the plurality of dies 120 to prevent cracking of the polymer layer 116. For example, when the processing temperature is greater than Tc of the polymer layer 116, the force F may be greater than 3000 kg, such as within a range between about 3000 kg and about 4000 kg. On the other hand, when the processing temperature is less than Tc of the polymer layer 116, the force F may be less than about 2000 kg, such as within a range between about 1000 kg and about 2000 kg.

As described above, the Tc of the material of the polymer layer 116 may not be substantially greater than or less than the processing temperature, such as over or under 50° C. of the processing temperature. If the Tc of the material of the polymer layer 116 is greater than the processing temperature by over 50° C., the polymer layer 116 is too brittle or hard at the processing temperature during the die bonding process. As a result, the polymer layer 116 may crack. On the other hand, if the Tc of the material of the polymer layer 116 is less than the processing temperature by over 50° C., the polymer layer 116 is too ductile or soft at the processing temperature during the die bonding process. As a result, the force F from the membrane 114 may not be applied to the plurality of dies 120 uniformly through the polymer layer 116. Consequently, some of the dies 120 may not be bonded to the substrate 118.

Referring to FIG. 1D and FIG. 2 (block 240), the membrane 114 is deflated to remove the force F from the plurality of dies 120 and to return the polymer layer 116 to the point of initial contact with the edge ring 112 (e.g., via the release film 122) with the membrane 114 at the threshold volume (same state as FIG. 1B). As the polymer layer 116 separates from the plurality of dies 120, the release film 122 enables a clear separation. If the release film 122 is not present, one or more dies 120 may stick to the polymer layer 116 and de-bond from the substrate 118. In some embodiments, the process at block 240 may occur over a fourth time period T4 within a range between about 60 seconds and about 120 seconds, such as about 90 seconds.

Referring to FIG. 1E and FIG. 2 (block 250), the membrane 114 is further deflated to contract the membrane 114, and the polymer layer 116 attached to the membrane 114, upwards away from the substrate 118. In some embodiments, the further deflation of the membrane 114 at block 250 may coincide with venting pressure from the processing region 108. As the membrane 114 is deflated, the vertical distance between the bottom surface of the polymer layer 116 and the top surface of the edge ring 112 increases until the membrane 114 returns to the original state (same state as FIG. 1A). Tension in the release film 122 peels the release film 122 away from the polymer layer 116 as the membrane 114 deflates. In some embodiments, the process at block 250 may occur over a fifth time period T5 within a range between about 60 seconds and about 120 seconds, such as about 90 seconds.

Referring to FIG. 2 (block 260), the substrate 118 and the plurality of dies 120 that are bonded to the substrate 118 are transferred, via the robot handler, from the substrate support 110 to the factory interface. In some embodiments, the bonding tool 100 is communicatively coupled with and/or includes a controller 124 (FIGS. 1A-1E). The controller 124 may be a workstation computer, a desktop computer, a laptop computer, a tablet computer, or any other type of computing device comprising one or more software products that are capable of controlling processes (e.g., based on input/output of certain operational parameters), receiving process feedback, receiving test result data, performing process adjustments, and/or other software-related control schemes. In some embodiments, the controller 124 includes a processor 126 and a memory 128. The processor 126 may include a central processing unit (CPU), a graphics processing unit (GPU), a microprocessor, and/or other processing units or components. The memory 128 may be implemented as computer-readable storage media (CRSM), which may be any available physical media accessible by the processor 126 to execute instructions stored on the memory 128. The memory 128 may be capable of storing various computer readable instructions for performing certain operations described herein (e.g., operations of the controller 124). The instructions, when executed by the processor 126, may cause certain operations described herein to be performed. The controller 124 can be communicatively coupled with and control the bonding tool 100 and various equipment (e.g., robot handler, pumps, gas sources, valves, sensors, and other equipment) associated with the bonding tool 100 to implement one or more aspects of the method 200. For example, the controller 124 can control one or more process timings (e.g., T1, T2, T3, T4, T5), temperatures, pressures, forces, and movements described in connection with FIG. 2. In some embodiments, the controller 124 can be configured to implement all blocks of the method 200 for bonding one or more dies onto a substrate using the bonding tool 100.

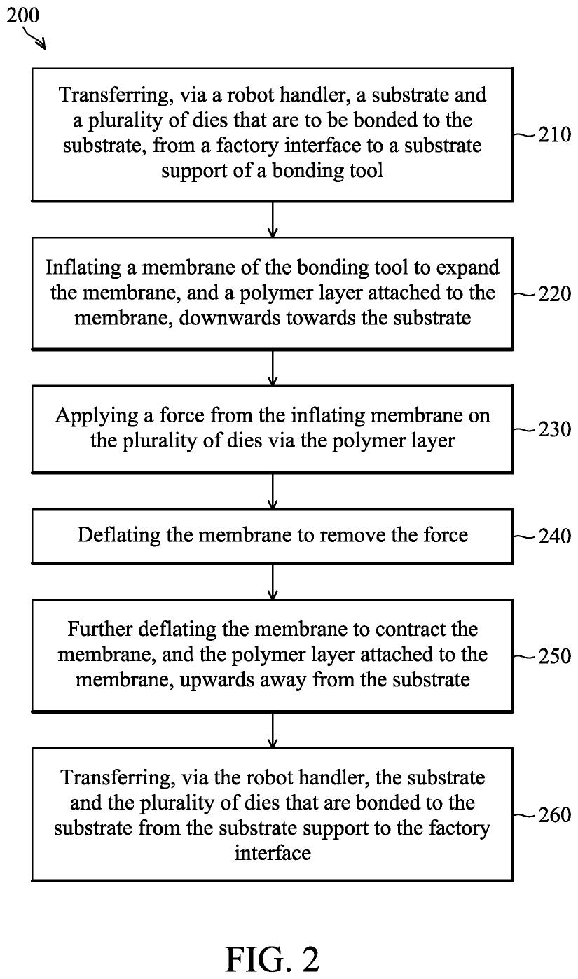

FIG. 3 is a perspective view of a membrane assembly 300 that includes the membrane 114 with the polymer layer 116 attached, in accordance with some embodiments. The membrane assembly 300 can be attached to the upper tray 104 via a flange 302 that is around an outside portion of the membrane 114. In some embodiments, the flange 302 may be formed from metal (e.g., stainless steel). The flange 302 may include a plurality of holes 304 that are configured to receive respective fasteners (e.g., screws) that can be used to couple the membrane assembly 300 to the upper tray 104 (FIG. 1A) via respective threaded holes in the upper tray 104. As shown in FIG. 3, the plurality of holes 304 may be spaced around the circumference of the flange 302. In some embodiments, the polymer layer 116 may be a circular disc that matches the shape of the edge ring 112 (FIG. 1A). A diameter d1 of the polymer layer 116 may depend on the size of the bonding tool 100 (FIG. 1A) and, in particular, the size of a substrate that is able to fit in the bonding tool 100. For example, when the substrate is a 300 mm wafer, the diameter d1 of the polymer layer 116 may be within a range between about 310 mm and about 360 mm. In another example, when the substrate is a 200 mm wafer, the diameter d1 of the polymer layer 116 may be within a range between about 210 mm and about 260 mm. In another example, when the substrate is a 450 mm wafer, the diameter d1 of the polymer layer 116 may be within a range between about 460 mm and about 510 mm. As shown in FIG. 3, the polymer layer 116 is radially centered with respect to the membrane 114 and the flange 302. There is an annular gap 306 between the flange 302 and the polymer layer 116. In some embodiments, the annular gap 306 may be within a range between about 20 mm and about 45 mm.

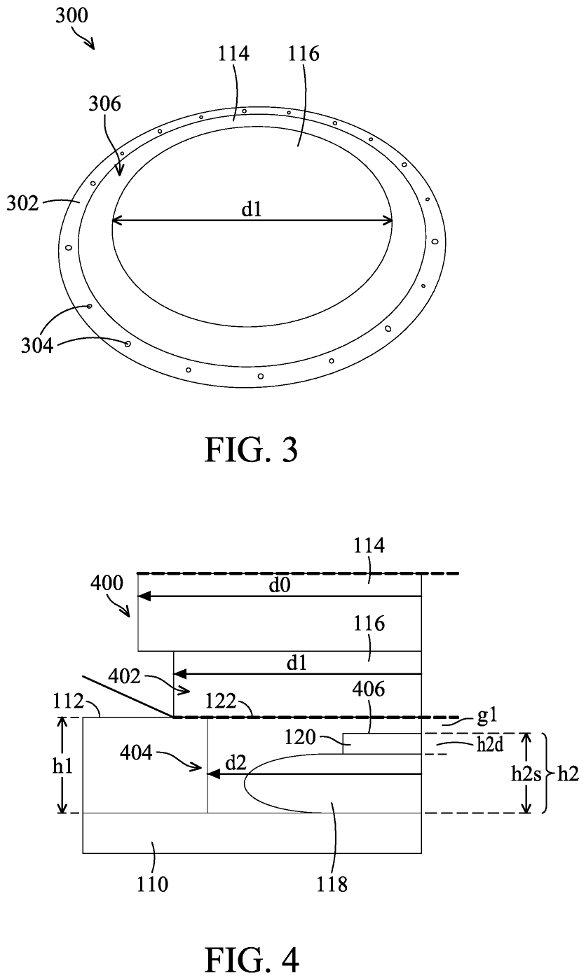

FIG. 4 is a partial sectional view that illustrates an inflation state 400 of bonding a die 120 onto the substrate 118, in accordance with some embodiments. As shown in FIG. 4, the inflation state 400 is consistent with the membrane 114 being inflated to the point of initial contact of the polymer layer 116 (via the release film 122) with the edge ring 112 as described above in connection with FIG. 1B and FIG. 2 (block 220). As shown in FIG. 4, the diameter d1 of the polymer layer 116 is substantially smaller than a diameter do of the membrane 114 (e.g., when the membrane 114 is deflated). As shown in FIG. 4, the diameter d1 of the polymer layer 116 is greater than an inner diameter d2 of the edge ring 112 such that an outer portion 402 of the polymer layer 116 overlaps with and rests on an inner portion 404 of the edge ring 112. In some embodiments, the diameter d1 of the polymer layer 116 may be 5% to 20% greater than the inner diameter d2 of the edge ring 112. As shown in FIG. 4, there is a gap g1 between a top surface 406 of a die, of the plurality of dies 120, and the bottom surface of the release film 122. In some embodiments, the gap g1 may range from about 80 μm to about 120 μm, such as from about 90 μm to about 110 μm, such as about 100 μm. The size of the gap g1 may be beneficial to cause the force F to be uniformly applied on the plurality of dies 120. For example, when the gap g1 is greater than about 120 μm, the effective force that is applied to one or more dies 120 toward the edge of the substrate 118 may be less than desired (e.g., due to the outer portion 402 of the polymer layer 116 being held in place by resting on the edge ring 112). On the other hand, in some embodiments, when the gap g1 is less than about 80 μm, the effective force that is applied to one or more dies 120 toward the center of the substrate 118 may be greater than desired (e.g., greater than a threshold that can cause one or more dies 120 to crack). As illustrated in FIG. 4, the gap g1 is based on a height h1 of the edge ring 112 in relation to the combined height h2 of the substrate 118 (height, or thickness, h2s) and the plurality of dies 120 (height, or thickness, h2d). In other words, the gap g1 is the difference between the height h1 and the combined height h2. In some embodiments, a ratio of h1/h2 may be within a range between about 1.07 to about 1.11, such as about 1.09. In some embodiments, the height h1 of the edge ring 112 may be about 1.2 mm and the combined height h2 may be about 1.1 mm (e.g., including the height h2s of the substrate 118 that may be within a range between about 0.725 mm and about 0.775 mm and the height h2d of the plurality of dies 120 that may be within a range between about 0.325 mm and about 0.375 mm). In some embodiments, a ratio of h2s/h2d may be within a range between about 1.9 and about 2.4, such as between about 2.1 and 2.2.

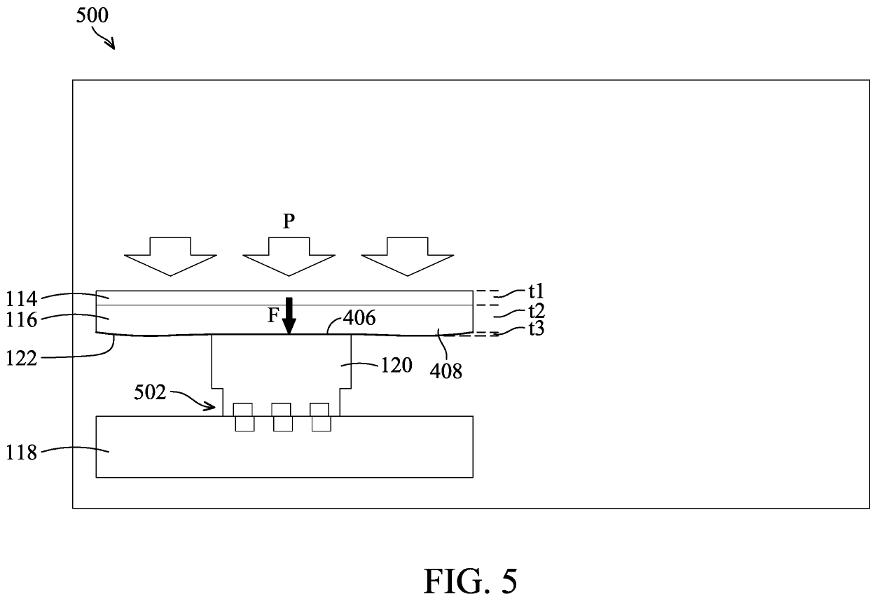

FIG. 5 is a schematic partial sectional view that illustrates a force application state 500 of bonding a die 120 onto the substrate 118, in accordance with some embodiments. As shown in FIG. 5, the force application state 500 is consistent with the polymer layer 116 being in contact (e.g., indirectly via the release film 122) with the plurality of dies 120 and the membrane 114 being inflated to the target pressure that applies the force F, as described above in connection with FIG. 1C and FIG. 2 (block 230). As shown in FIG. 5, membrane pressure P is applied on a backside of the membrane 114 that faces away from the polymer layer 116. In some embodiments, a thickness t1 of the membrane 114 may be within a range between about 2 mm and about 4 mm, such as about 3 mm. The thickness t1 is the actual thickness of the membrane 114 and not the thickness of the inflated membrane 114. In some embodiments, a thickness t2 of the polymer layer 116 may be within a range between about 6 mm and about 10 mm, such as between about 7 mm and about 9 mm, such as about 8 mm. In some embodiments, a thickness t3 of the release film 122 may be within a range between about 20 μm and about 80 μm, such as about 50 μm.

As shown in FIG. 5, the polymer layer 116 may be substantially flat when the force F is being applied on the plurality of dies 120. When the polymer layer 116 is substantially flat, a bottom surface 408 of the polymer layer 116 is parallel to the top surface 406 of the die 120. Therefore, the force F is applied primarily to the top surface 406 of the die 120 and in a direction that is substantially perpendicular to a bonding interface between the die 120 and the substrate 118. This is beneficial to align structures 502 and to prevent shifting of the die 120 with respect to the substrate 118, which can cause misalignment of structures 502, such as conductive features, which is a problem that can occur when conventional bonding tools are used without a polymer layer as disclosed herein. An example of misalignment that can result from non-uniform application of force is shown in phantom.

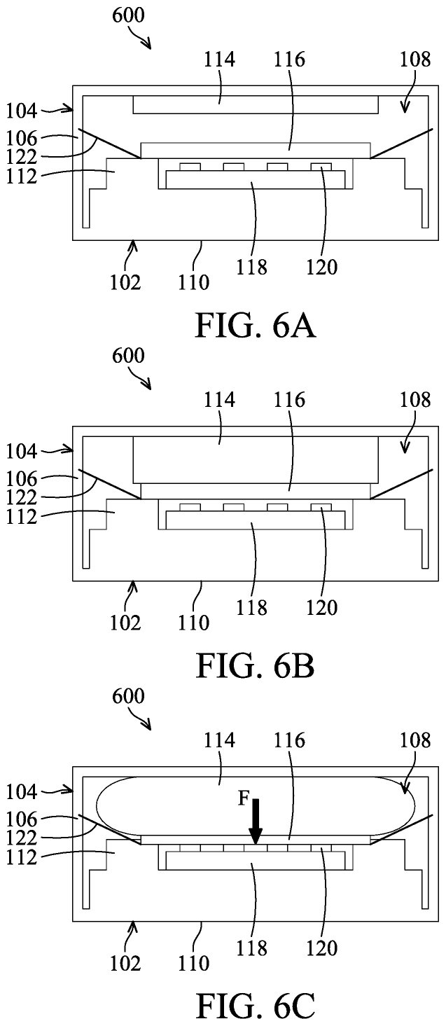

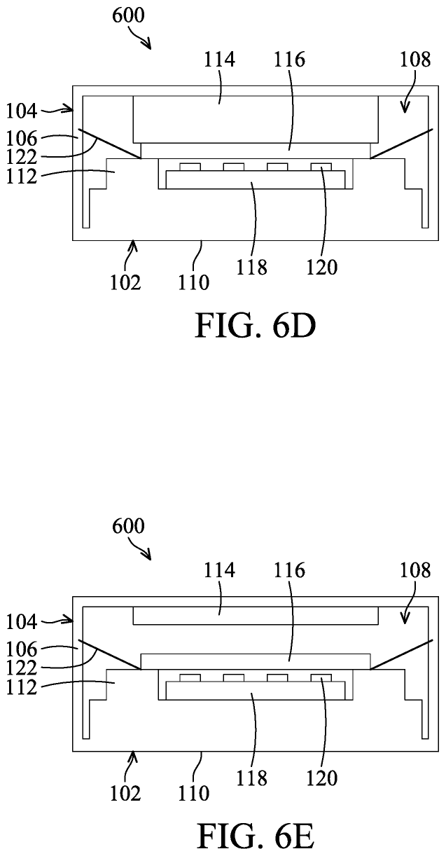

FIGS. 6A-6E illustrate views of various stages of bonding dies onto a substrate, in accordance with some embodiments. FIG. 7 is a flowchart that illustrates an alternative method 700 of bonding dies onto a substrate, in accordance with some embodiments. Aspects of the method 700 that are the same as the method 200 (FIG. 2) are indicated with reference numerals 210, 230, 240 and 260, and any description in connection therewith is incorporated into the method 700 without limitation. Referring to FIG. 7 (block 210), a substrate 118 and a plurality of dies 120 that are to be bonded to the substrate 118 are transferred, via a robot handler, from a factory interface to a substrate support 110 of a bonding tool 600. Referring to FIG. 6A and FIG. 7 (block 710), the bonding tool 600 is opened and the polymer layer 116 is manually placed over the edge ring 112. The polymer layer 116 may be placed on the edge ring 112 with the release film 122 disposed below the polymer layer 116. The process described in connection with FIGS. 6A-6E and FIG. 7 may be referred to as a “manual handling” process because the polymer layer 116 is not attached to the membrane 114 and is handled by an operator during the process. Referring to FIG. 6B and FIG. 7 (block 720), the membrane 114 of the bonding tool 600 is inflated to expand the membrane 114 downwards towards the substrate 118 and to engage the polymer layer 116. The process timings described above in connection with block 220 may be incorporated into block 720, without limitation. Referring to FIG. 6C and FIG. 7 (block 230), a force F is applied from the inflating membrane 114 on the plurality of dies 120 via the polymer layer 116. Referring to FIG. 6D and FIG. 7 (block 240), the membrane 114 is deflated to remove the force F from the plurality of dies 120 and to return the polymer layer 116 to the point of initial contact (e.g., via the release film 122) with the edge ring 112 with the membrane 114 at the threshold volume (same state as FIG. 6B). Referring to FIG. 6E and FIG. 7 (block 730), the membrane 114 is further deflated to contract the membrane 114 upwards away from the substrate 118 and to disengage the polymer layer 116. The process timings described above in connection with block 250 may be incorporated into block 730, without limitation. Referring to FIG. 7 (block 740), the bonding tool 600 is opened and the polymer layer 116 is manually removed from the edge ring 112, and the used release film 122 is moved away from the processing region 108. Referring to FIG. 7 (block 260), the substrate 118 and the plurality of dies 120 that are bonded to the substrate 118 are transferred, via the robot handler, from the substrate support 110 to the factory interface. The manual handling process requires the process to be stopped at two different times per cycle in order to place and remove the polymer layer. Accordingly, the auto handling process (FIG. 2) can be beneficial in the industry to result in a more efficient process with shorter cycle time and higher throughput compared to the manual handling process (FIG. 7). In some embodiments, the bonding tool 600 is communicatively coupled with and/or includes a controller 624. The controller 624 may be a workstation computer, a desktop computer, a laptop computer, a tablet computer, or any other type of computing device comprising one or more software products that are capable of controlling processes (e.g., based on input/output of certain operational parameters), receiving process feedback, receiving test result data, performing process adjustments, and/or other software-related control schemes. In some embodiments, the controller 624 includes a processor 626 and a memory 628. The processor 626 may include a central processing unit (CPU), a graphics processing unit (GPU), a microprocessor, and/or other processing units or components. The memory 628 may be implemented as computer-readable storage media (CRSM), which may be any available physical media accessible by the processor 626 to execute instructions stored on the memory 628. The memory 628 may be capable of storing various computer readable instructions for performing certain operations described herein (e.g., operations of the controller 624). The instructions, when executed by the processor 626, may cause certain operations described herein to be performed. The controller 624 can be communicatively coupled with and control the bonding tool 600 and various equipment (e.g., robot handler, pumps, gas sources, valves, sensors, and other equipment) associated with the bonding tool 600 to implement one or more aspects of the method 700. For example, the controller 624 can control one or more process timings (e.g., T1, T2, T3, T4, T5), temperatures, pressures, forces, and movements described in connection with FIG. 7. In some embodiments, the controller 624 can be configured to implement all blocks of the method 700 for bonding one or more dies onto a substrate using the bonding tool 600.

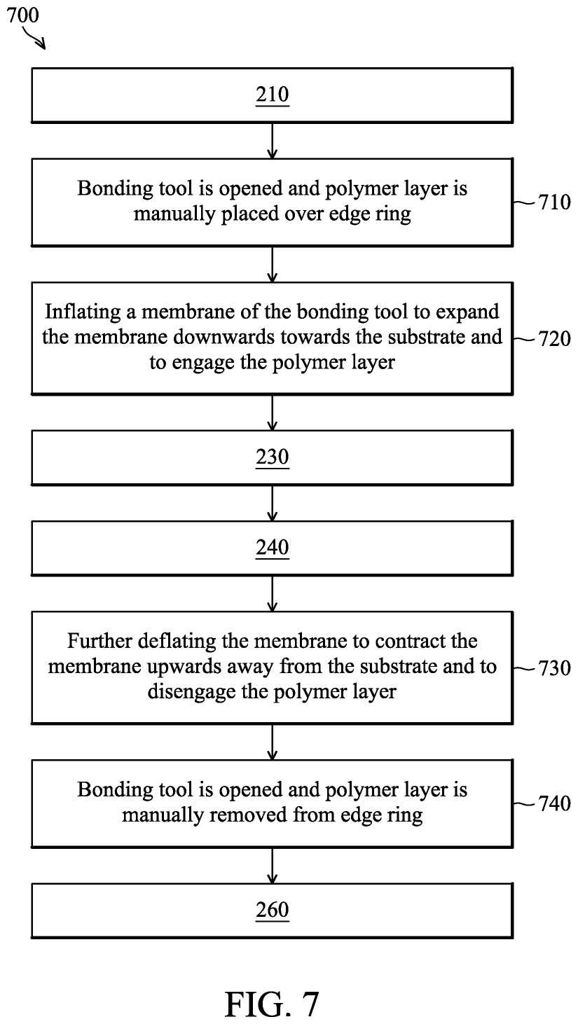

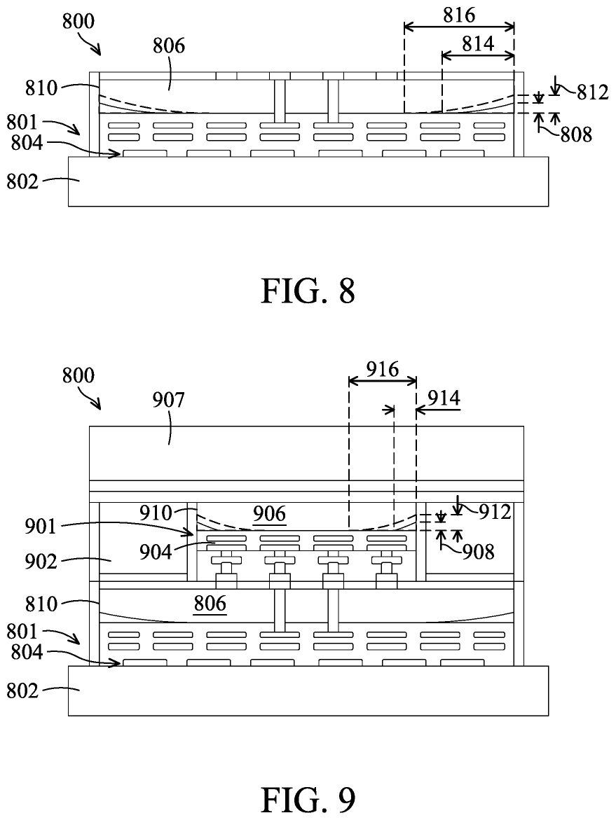

FIG. 8 is a schematic sectional view that illustrates a first bonding step of forming a semiconductor device package 800, in accordance with some embodiments. FIG. 9 is a schematic sectional view that illustrates a second bonding step of forming the device structure 800, in accordance with some embodiments. The first bonding steps and the second bonding step are exemplary illustrations of a process that uses the bonding tool 100 or the bonding tool 600 including the polymer layer 116, as described herein. Referring to FIG. 8, the semiconductor device package 800 includes a temporary substrate 802 and a first die 801 bonded to the temporary substrate 802. The first die 801 may include a substrate 806 and an interconnection structure 804. In some embodiments, the first die 801 may be, or include, a central processing unit (CPU).

In some embodiments, due to significant mismatch between the coefficients of thermal expansion (CTEs) of the materials of the first die 801, warpage of the substrate 806 of the first die 801 may occur. For example, as shown in FIG. 8, the warpage of the substrate 806 of the first die 801 can lead to delamination, such that vertical gaps 808 are formed around an outer edge 810 of the first die 801. The warpage that results from the first bonding step, with the polymer layer 116 as described herein, is reduced compared to a warpage that results from die bonding without the polymer layer 116. The warpage resulting from die bonding without the polymer layer 116 can create vertical gaps 812 (shown in phantom). In some embodiments, the vertical gap 808 may be within a range between about 11 μm and about 15 μm, while the vertical gap 812 may be within a range between about 14 μm and about 19 μm. In some embodiments, using the polymer layer 116 can reduce warpage by about 20% or more, such as about 20% to about 30%, such as about 30%. As shown in FIG. 8, the delamination as a result of warpage that results from the first bonding step may also include a radial gap 814 around the outer edge 810 of the first die 801. The radial gap 814 is reduced compared to radial gaps 816 (shown in phantom) that result from die bonding without the polymer layer 116. In some embodiments, the radial gap 814 may be about 200 μm or less, such as within a range between about 0 μm and about 200 μm, such as between about 0 μm and 100 μm, such as about 0 μm, or between about 3 μm and about 20 μm, such as about 3 μm. In some embodiments, the radial gap 816 may be about 200 μm or more, such as within a range between about 200 μm and about 300 μm, such as about 300 μm.

As shown in FIG. 9, the second bonding step forms a bond between a second die 901 and the first die 801. Similar to the first die 801, the second die 901 includes a substrate 906 and an interconnection structure 904, and the substrate 906 may have a warpage. The warpage of the substrate 906 can lead to delamination, such that vertical gaps 908 are formed around an outer edge 910 of the second die 901. The warpage that results from the second bonding step, with the polymer layer 116 as described herein, is reduced compared to a warpage that results from die bonding without the polymer layer 116. The warpage resulting from die bonding without the polymer layer 116 can create vertical gaps 912 (shown in phantom). In some embodiments, the vertical gap 908 may be within a range between about 4 μm and about 5.5 μm, while the vertical gap 912 may be within a range between about 5 μm and about 7 μm. In some embodiments, using the polymer layer 116 can reduce warpage by about 20% or more, such as about 20% to about 30%, such as about 30%. As shown in FIG. 9, the delamination as a result of warpage that results from the second bonding step may also include a radial gap 914 around the outer edge 910 of the second die 901. The radial gap 914 is reduced compared to radial gaps 916 (shown in phantom) that results from die bonding without the polymer layer 116. In some embodiments, the radial gap 914 may be about 100 μm or less, such as within a range between about 0 μm and about 100 μm, such as between about 0 μm and 50 μm, such as about 0 μm, or between about 3 μm and about 20 μm, such as about 3 μm. In some embodiments, the radial gap 916 may be about 100 μm or more, such as within a range between about 100 μm and about 200 μm, such as about 120 μm. The semiconductor device package 800 may include one or more dummy structures 902 outside the second die 901 and a carrier substrate 907 over the second die 901. In some embodiments, the second die 901 may be, or include, a static random-access memory (SRAM). After the bonding of the first and second dies 801, 901, the temporary substrate 802 and the carrier substrate 907 may be removed, and the resulting package may be a chip-on-wafer (CoW) package.

Embodiments of the present disclosure provide a bonding tool for bonding dies onto substrates and methods of use. In some embodiments, a method includes positioning a substrate and a plurality of dies over a substrate support of a bonding tool, wherein the plurality of dies are disposed on the substrate, and the substrate is surrounded by an edge ring; inflating a membrane of the bonding tool disposed above the substrate and the edge ring to expand the membrane downwards, wherein a polyetheretherketone (PEEK) layer attached to the membrane rests on the edge ring; and applying a force from the inflating membrane on the plurality of dies via the PEEK layer.

In some embodiments, a method includes positioning a substrate and a plurality of dies over a substrate support of a bonding tool, wherein the plurality of dies are disposed on the substrate, and the substrate is surrounded by an edge ring; inflating a membrane of the bonding tool disposed above the substrate and the edge ring to expand the membrane downwards, wherein a polymer layer attached to the membrane rests on the edge ring, and the polymer layer has a diameter smaller than a diameter of the membrane when the membrane is deflated; and applying a force from the inflating membrane on the plurality of dies via the polymer layer.

In some embodiments, a method includes positioning a substrate and a plurality of dies over a substrate support of a bonding tool, wherein the plurality of dies are disposed on the substrate, and the substrate is surrounded by an edge ring; placing a polymer layer on the edge ring, wherein a gap between a top surface of a die of the plurality of dies and a bottom surface of the polymer layer ranges from about 80 μm to about 120 μm; and inflating a membrane of the bonding tool disposed above the substrate and the edge ring to apply a force on the plurality of dies via the polymer layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
positioning a substrate and a plurality of dies over a substrate support of a bonding tool, wherein the plurality of dies are disposed on the substrate, and the substrate is surrounded by an edge ring;
inflating a membrane of the bonding tool disposed above the substrate and the edge ring to expand the membrane downwards, wherein a polyetheretherketone (PEEK) layer attached to the membrane rests on the edge ring; and
applying a force from the inflating membrane on the plurality of dies via the PEEK layer.

2. The method of claim 1, wherein the edge ring has a height greater than a combined height of the substrate and a die of the plurality of dies.

3. The method of claim 1, wherein the substrate support is attached to a lower tray of the bonding tool and the membrane is attached to an upper tray of the bonding tool.

4. The method of claim 3, further comprising controlling respective temperatures of the upper tray and the lower tray, wherein the respective temperatures are configured to be controlled independently.

5. The method of claim 4, further comprising:
maintaining the respective temperatures of the upper tray and the lower tray, relative to a glass transition temperature (Tc) of the PEEK layer, within a range between about −40° C. and about +30° C. with respect to the Tc.

6. The method of claim 1, wherein a processing temperature of the bonding tool is greater than a glass transition temperature (Tc) of the PEEK layer, and wherein the force is within a range between about 3000 kg and about 4000 kg.

7. The method of claim 1, wherein a processing temperature of the bonding tool is less than a glass transition temperature (Tc) of the PEEK layer, and wherein the force is within a range between about 1000 kg and about 2000 kg.

8. A method, comprising:
positioning a substrate and a plurality of dies over a substrate support of a bonding tool, wherein the plurality of dies are disposed on the substrate, and the substrate is surrounded by an edge ring;
inflating a membrane of the bonding tool disposed above the substrate and the edge ring to expand the membrane downwards, wherein a polymer layer attached to the membrane rests on the edge ring, and the polymer layer has a diameter smaller than a diameter of the membrane when the membrane is deflated; and
applying a force from the inflating membrane on the plurality of dies via the polymer layer.

9. The method of claim 8, wherein the polymer layer has an elasticity smaller than an elasticity of the membrane.

10. The method of claim 8, wherein inflating the membrane further comprises causing a bottom surface of the polymer layer to be in contact with a release film that is positioned between the polymer layer and the plurality of dies.

11. The method of claim 8, wherein the edge ring has a height substantially greater than a combined height of the substrate and a die of the plurality of dies.

12. The method of claim 11, wherein the height of the edge ring is greater than the combined height of the substrate and the die by about 80 μm to about 120 μm.

13. The method of claim 8, wherein the polymer layer comprises polyetheretherketone (PEEK).

14. The method of claim 8, wherein the diameter of the polymer layer is 5% to 20% greater than an inner diameter of the edge ring.

15. A method, comprising:
positioning a substrate and a plurality of dies over a substrate support of a bonding tool, wherein the plurality of dies are disposed on the substrate, and the substrate is surrounded by an edge ring;
placing a polymer layer and a release film on the edge ring, wherein a gap between a top surface of a die of the plurality of dies and a bottom surface of the release film ranges from about 80 μm to about 120 μm; and
inflating a membrane of the bonding tool disposed above the substrate and the edge ring to apply a force on the plurality of dies via the polymer layer.

16. The method of claim 15, wherein the polymer layer comprises polyetheretherketone (PEEK).

17. The method of claim 15, wherein a diameter of the polymer layer is 5% to 20% greater than an inner diameter of the edge ring.

18. The method of claim 15, wherein the membrane comprises silicone.

19. The method of claim 15, wherein inflating the membrane further comprises:
causing an inner radial portion of the polymer layer to advance across the gap to rest on the plurality of dies.

20. The method of claim 19, wherein a bottom surface of the inner radial portion of the polymer layer is substantially flat when the force is being applied on the plurality of dies.
